(19) United States
(12) Patent Application Publication
(10) Pub. No.: US 2018/0097325 A1
(43) Pub. Date: Apr. 5, 2018

(54) Corrosion Protection System and Method for Use with Electrical Contacts

(71) Applicant: Tyco Electronics Corporation, Berwyn, PA (US)

(72) Inventors: Rodney Ivan Martens, Mechanicsburg, PA (US); Martin William Bayes, Hummelstown, PA (US); Vincent Corona Pascucci, Mechanicsburg, PA (US); Daniel Briner Shreffler, Mechanicsburg, PA (US); Kevin Ray Leibold, New Cumberland, PA (US)

(21) Appl. No.: 15/284,112

(22) Filed: Oct. 3, 2016

(51) Int. Cl. H01R 43/00; H01R 13/03; C23C 14/30; C23C 14/14; C23C 18/42; C23C 18/31; C25D 7/00; C25D 3/46; C25D 3/38; C25D 3/22; C25D 3/12; C23F 15/00

(52) U.S. Cl. CPC H01R 43/002; H01R 13/03; C23C 14/30; C23C 14/14; C23C 18/42; C23F 15/00; C25D 7/00; C25D 3/46; C25D 3/38; C25D 3/22; C25D 3/12; C23C 18/31

(57) ABSTRACT

A method for inhibiting corrosion in metal components such as electrical contacts, comprising providing a component, wherein the component includes a first metal layer; a second metal layer deposited on the first metal layer; at least one additional metal layer deposited on the second metal layer; and an electrically active contact region on the uppermost layer of the at least one additional metal layer; and forming a defect in the component in at least one predetermined location around the electrically active contact region, wherein the defect passes through the at least one additional metal layer to expose the second metal layer, through the at least one additional metal layer and second metal layer to expose the first metal layer, or a combination thereof.

### BACKGROUND OF THE INVENTION

The described invention relates in general to corrosion protection and inhibition systems and methods, and more specifically to a system and method for providing corrosion protection to electrical contacts, particularly those plated with precious metals such as gold.

The utilization of gold and other precious metals in the electronics industry has been an ongoing aspect of the development and expanded use of complex digital electronics and equipment across numerous industry sectors. By some estimates, as much as 320 tons of gold is used each year in the electronics industry for computers, mobile phones, tablets, and other electronic devices. For electronics applications, gold provides the combined properties of electrical conductivity, ductility, and corrosion resistance at high or low temperatures. Corrosion resistance is one the most important properties of gold with regard to its use in electronics. The corrosion resistance of gold provides atomically clean metal surfaces which have an electrical contact resistance close to zero, while the high thermal conductivity of gold ensures rapid dissipation of heat when gold is used for electrical contacts. Gold is included in various electronics through the use of gold plating processes and gold plating is primarily used on electrical contacts for switches, relays, and connectors.

Gold plating is often used in electronics, particularly electrical connectors and printed circuit boards, for providing a corrosion-resistant electrically conductive layer on copper alloy or other substrate metals. With direct gold-on-copper plating, copper atoms tend to diffuse through the gold layer, causing tarnishing of its surface and formation of an oxide and/or sulphide layer. A layer of a suitable barrier metal, typically nickel, is often deposited on the substrate before the gold plating. This layer of nickel provides mechanical backing for the gold layer, thereby improving its wear resistance and reducing the severity of corrosion occurring at pores that might be present in the gold layer. Both the nickel and gold layers can be plated by electrolytic or electroless processes.

For connector applications in electronics that require reliability, any separable contact interface should be shielded from environmental deterioration. An application of gold onto the interface of a separable connector provides a long, stable and very low contact resistance for the component. Corrosive environments such as high humidity locations or an environment that contains corrosive pollutants such as chlorine or gaseous oxides of sulfur or nitrogen will attack and degrade metals such as nickel and the underlying copper alloy substrate and this corrosion will interfere with electrical contact. Gold does not break down in these conditions; however, if the gold plating is too thin or porous, nickel and copper-based corrosion products may emanate from small discontinuities in the gold layer so it is important for the plating to be applied at the correct thickness for full protection and with a suitable under layer metal. The determination of the correct gold plating thickness depends on the application of the electronic component. In general, a 0.8 micrometer (also referred to as micron) (30 micro inches) coating of hard gold over a minimum of 1.3 microns (50 micro inches) of nickel gives a degree of durability considered adequate for most connector applications. Increasing the thickness of a gold coating tends to decrease the porosity, which reduces the vulnerability of a contact to pore corrosion.

To avoid degradation of gold plating over copper or copper alloy substrates, especially in corrosive environments, gold plating should be applied over an under layer of a quality metal such as nickel. An under layer of nickel will act as the following for a gold plated surface: (i) a pore-corrosion inhibitor (e.g., nickel as an underplate inhibits corrosion by way of pores in thin areas of gold plating); (ii) a corrosion creep inhibitor (i.e., nickel provides a barrier against migration of corrosion onto the gold surface); (iii) a diffusion barrier (i.e., nickel prevents diffusion of other metals like copper or zinc into the gold surface); and (iv) mechanically supportive under layer for contacting surfaces (i.e., nickel increases the wear resistance of gold plating). Pore corrosion may be either intrinsic (i.e., a function of the plating or subsequent manufacturing process) or extrinsic (a function of the usage environment). Such pores or defects can be unavoidable due to thin layers of precious metal protection, or wear of the interface due to insertion cycles. Accordingly, there is an ongoing need for a system and method for preventing both pore corrosion and corrosion creep in electrical contacts plated with gold or other precious metals.

### SUMMARY OF THE INVENTION

The following provides a summary of certain exemplary embodiments of the present invention. This summary is not an extensive overview and is not intended to identify key or critical aspects or elements of the present invention or to delineate its scope.

In accordance with one aspect of the present invention, a first method for inhibiting corrosion in metal components such as electrical contacts is provided. This method includes providing a component, wherein the component includes a first metal layer; a second metal layer deposited on the first metal layer; at least one additional metal layer deposited on the second metal layer; and an electrically active contact region on the uppermost layer of the at least one additional metal layer; and forming a defect in the component in at least one predetermined location around the electrically active contact region, wherein the defect passes through the at least one additional metal layer to expose the second metal layer, through the at least one additional metal layer and second metal layer to expose the first metal layer, or a combination thereof.

In accordance with another aspect of the present invention, a second method for inhibiting corrosion in electrical components such as electrical contacts is provided. This method includes providing an electrical component, wherein the electrical component includes a first metal layer; a second metal layer deposited on the first metal layer; at least one additional metal layer deposited on the second metal layer; an electrically active contact region on the topmost layer of the at least one additional metal layer; and a lead-in region on the topmost metal layer in proximity to the electrically active contact region; forming a channel at a predetermined location around the electrically active contact region and lead-in region, wherein the at least one channel passes through the at least one additional metal layer to expose the second metal layer; and forming a defect in the component in at least one predetermined location around the at least one channel, wherein the defect passes through the at least one additional metal layer to expose the second metal layer, through the at least one additional metal layer and second metal layer to expose the first metal layer, or a combination thereof.

In yet another aspect of this invention, a third method for inhibiting corrosion in metal components is provided. This method includes providing a component, wherein the component includes an electrically active contact region; and forming a defect on the component in at least one predetermined location around the electrically active contact region, wherein the defect includes at least one sacrificial material deposited on the component.

Additional features and aspects of the present invention will become apparent to those of ordinary skill in the art upon reading and understanding the following detailed description of the exemplary embodiments. As will be appreciated by the skilled artisan, further embodiments of the invention are possible without departing from the scope and spirit of the invention. Accordingly, the drawings and associated descriptions are to be regarded as illustrative and not restrictive in nature.

### BRIEF DESCRIPTION OF THE DRAWINGS

The accompanying drawings, which are incorporated into and form a part of the specification, schematically illustrate one or more exemplary embodiments of the invention and, together with the general description given above and detailed description given below, serve to explain the principles of the invention.

FIG. 1 is a photograph of an array of intentionally induced defects formed in a multilayer metal construct, wherein a substrate layer of metal has been exposed, and wherein the outer defects in the array are experiencing greater corrosion, thereby effectively shielding the inner defects in the array.

FIG. 2 is a top view of a multilayer electrical metal component in accordance with an exemplary embodiment of the present invention, wherein a plurality of intentionally induced defects have been formed in proximity to an electrically active contact region and lead-in region for exposing a substrate layer of metal, and wherein at least one channel has been formed around the electrically active contact region and lead-in region for exposing a substrate layer of metal.

### DETAILED DESCRIPTION OF THE INVENTION

Exemplary embodiments of the present invention are now described with reference to the Figures. Reference numerals are used throughout the detailed description to refer to the various elements and structures. Although the following detailed description contains many specifics for the purposes of illustration, a person of ordinary skill in the art will appreciate that many variations and alterations to the following details are within the scope of the invention. Accordingly, the following embodiments of the invention are set forth without any loss of generality to, and without imposing limitations upon, the claimed invention.

As previously stated, the present invention relates in general to corrosion protection and inhibition systems and methods and more specifically to a system and method for providing corrosion protection to electrical contacts, particularly those plated with precious metals such as gold. Electrical contacts located on the outside perimeter of an array have the tendency to exhibit greater degrees of corrosion than those on the inside of an array because, presumably, they are more exposed to the high rates of gas exchange with the environment, or because they act as scavenging elements. Various embodiments of this invention mimic this effect at the microscopic level (or at the macroscopic level) and preferentially drive corrosion sufficiently near a contact interface to inhibit corrosion. This is accomplished by inducing certain defects and/or adding certain reactive materials at or near the active contact interface. These deliberately induced defects and/or added reactive materials function as high capacity corrosion “sinks” that locally deplete reactive agents (e.g., corrosive gases) in the environment in which the electrical contact is located and utilized. At least one defect is present, while in some embodiments a plurality of defects, which may be in any form, are present. For example, the plurality of defects may include a single line of individual defects formed partially or completely around the electrically active contact region, or the plurality of defects may be an array of individual defects formed partially or completely around the electrically active contact region.

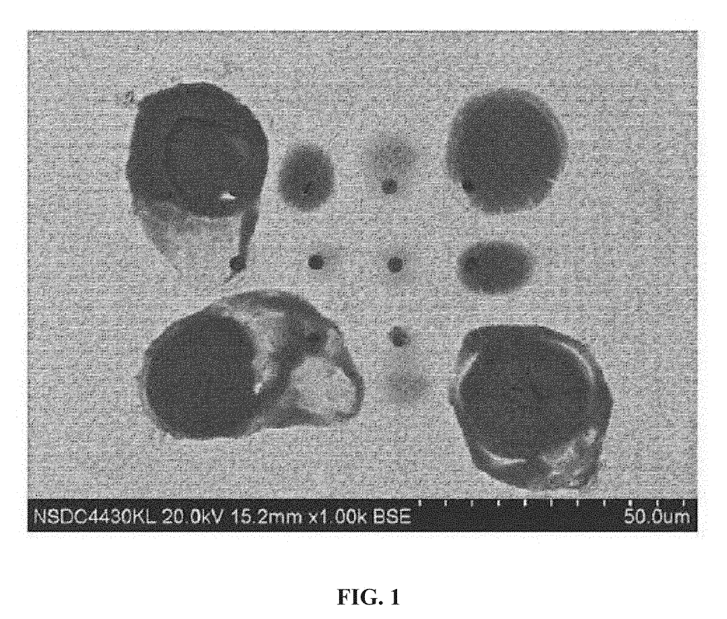

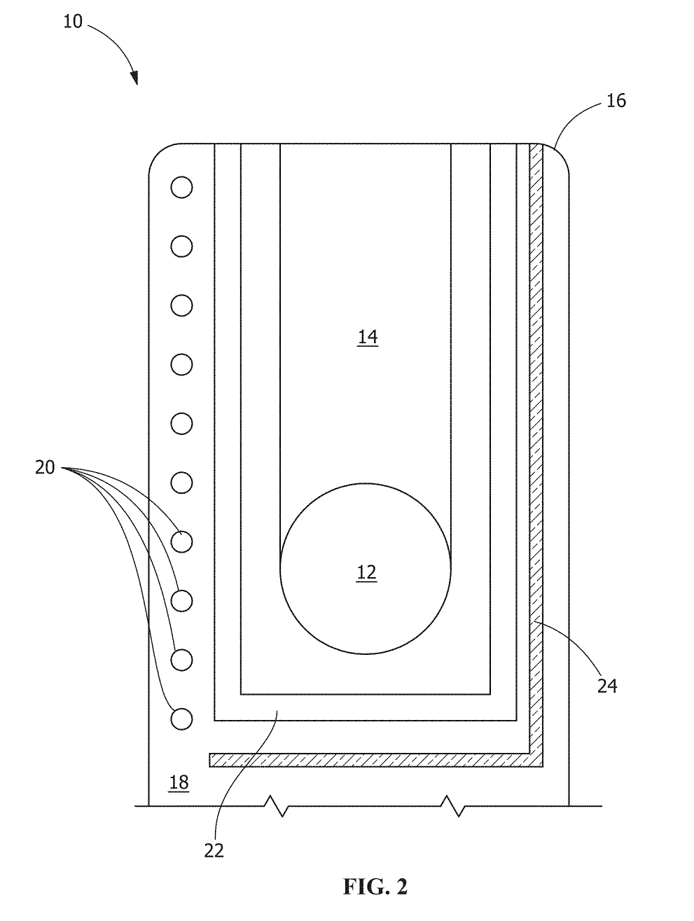

With reference to the Figures, FIG. 1 is a photograph of an array of intentionally induced defects formed in a multilayer metal construct, wherein a substrate layer of metal has been exposed, and wherein the outer defects in the array are experiencing greater corrosion, thereby effectively shielding the inner defects in the array. The preferential corrosion of the outermost induced defects in FIG. 1 is an important aspect of this invention with regard to placement of the induced defects relative to the area or region to be protected. In heterogeneous microenvironments wherein the outermost induced defects are exposed to higher volumes or higher flow rates of corrosive gases, the diffusional fields of the outer defects are typically much larger than the diffusional fields of the inner induced defects (see FIG. 1). This “quadrant effect” is one basis that may be used for determining proper or optimized placement of the induced defects relative to one another and relative to the area to be protected. FIG. 2 is a top view of a multilayer electrical metal component in accordance with an exemplary embodiment of the present invention, wherein a plurality of intentionally induced defects have been formed in proximity to an electrically active contact region and lead-in region for exposing a substrate layer of metal, and wherein at least one channel has been formed around the electrically active contact region and lead-in region for exposing a substrate layer of metal.

In FIG. 2, metal component 10, which is a generic electrical connector, includes electrically active contact area or region 12, lead-in region 14, and header contact 16. Upper surface 18 of metal component 10 includes a series of induced defects 20, inner channel 22, and outer channel 24. In an exemplary embodiment, metal component 10 is a multi-layer construct or stack that includes a first layer of copper or copper alloy, a second layer of nickel or a material having properties and/or functions similar to those of nickel (e.g., corrosion inhibition, diffusion barrier, wear resistance), deposited on the first layer of copper, and a third (i.e. additional) layer of gold or other precious metal deposited on the second layer of nickel. A series of induced defects 20 is located around or near active contact region 12 and lead-in region 14 and passes through the third and second layers to expose the first layer of copper or, alternately, passes through the third layer to expose the second layer of nickel. In some embodiments, the series of induced defects 20 includes both exposed copper and exposed nickel. In addition to induced defects 20, or as an alternative to induced defects 20, outer channel 24 may be included for exposing the copper first layer (or the nickel second layer). Induced defects 20 and/or outer channel 24 provide sacrificial corrosion protection for active contact region 12 and lead-in region 14 by scavenging corrosive gases present in an operating environment for metal component 10. As shown in FIG. 2, in some embodiments of the present invention, inner channel 22 is located around active contact region 12 and lead-in region 14 and is positioned between induced defects 20 and/or outer channel 24. Inner channel 24 typically exposes the nickel layer and provides a creep dam to prevent any creep corrosion occurring at induced defects 20 and/or outer channel 24 from migrating into active contact region 12 and lead-in region 14. In other embodiments of this invention, metal component 10 is a multi-layer construct or stack that includes, in one example, a first layer of copper or copper alloy, a second layer of nickel or a material having properties and/or functions similar to those of nickel, deposited on the first layer of copper, a third layer of palladium-nickel, and a fourth layer of gold or other precious metal deposited on the third layer. Other constructs with numerous multiple layers of metals (i.e. additional layers) are compatible the methods of this invention.

In some embodiments of the present invention, induced defects 20 are created with focused ion beam (FIB) techniques, which are commonly used in the semiconductor industry, in materials science, and for site-specific analysis, deposition, and ablation of various materials. A FIB apparatus resembles a scanning electron microscope (SEM); however, while the SEM uses a focused beam of electrons, a FIB apparatus uses a focused beam of ions. Various lasers and other materials processing systems and methods may be used to create induced defects 20, each of which may have a circular geometry or other specific geometry. Such other materials processing systems and methods include photolithographic masking/etching and various alternate mechanical processes capable of inducing defects. Induced defects 20 may be created in a ring around an area to be protected or may be positioned in any number of different predetermined or application-specific patterns. Induced defects 20 may be utilized in micro applications (e.g., small areas in the tens of microns) or in macro applications that include sacrificial pins or other structures used in larger contracts, connectors, adapters, and the like. Induced defects 20 may be formed as multiple discrete defects or as a single continuous defect.

In other embodiments of the present invention, induced defects 20 include sacrificial materials that are deposited on upper surface 18 rather than sacrificial materials that are exposed by removing portions of upper surface 18. In these embodiments, suitable sacrificial materials include copper, silver, zinc, or a combination thereof and these materials may be deposited in individual spots, rows, as arrays, as strips, or in numerous other patterns. Induced defects 20 may be formed using plating techniques known to those skilled in the art, e-beam deposition, ink-jetting, or combinations thereof.

While the present invention has been illustrated by the description of exemplary embodiments thereof, and while the embodiments have been described in certain detail, there is no intention to restrict or in any way limit the scope of the appended claims to such detail. Additional advantages and modifications will readily appear to those skilled in the art. Therefore, the invention in its broader aspects is not limited to any of the specific details, representative devices and methods, and/or illustrative examples shown and described. Accordingly, departures may be made from such details without departing from the spirit or scope of the general inventive concept.

What is claimed is:

1. A method for inhibiting corrosion in metal components, comprising:
(a) providing a component, wherein the component includes:
(i) a first metal layer;
(ii) a second metal layer deposited on the first metal layer;
(iii) at least one additional metal layer deposited on the second metal layer; and
(iv) an electrically active contact region on the uppermost layer of the at least one additional metal layer; and
(b) forming a defect in the component in at least one predetermined location around the electrically active contact region, wherein the defect passes through the at least one additional metal layer to expose the second metal layer, through the at least one additional metal layer and second metal layer to expose the first metal layer, or a combination thereof.

2. The method of claim 1, wherein the first metal layer comprises copper or a copper alloy

3. The method of claim 1, wherein the second metal layer comprises nickel.

4. The method of claim 1, wherein the at least one additional metal layer comprises a precious metal.

5. The method of claim 1, wherein the defect is formed using a focused ion beam.

6. The method of claim 1, further comprising a plurality of defects, wherein the plurality of defects includes (a) a single line of individual defects formed partially or completely around the electrically active contact region, or (b) an array of individual defects formed partially or completely around the electrically active contact region.

7. The method of claim 1, wherein the defect includes a single continuous defect formed partially or completely around the electrically active contact region.

8. A method for inhibiting corrosion in electrical components, comprising:
(a) providing an electrical component, wherein the electrical component includes:
(i) a first metal layer;
(ii) a second metal layer deposited on the first metal layer;
(iii) at least one additional metal layer deposited on the second metal layer;
(iv) an electrically active contact region on the uppermost layer of the at least one additional metal layer; and
(v) a lead-in region on the uppermost metal layer in proximity to the electrically active contact region;
(b) forming at least one channel at a predetermined location around the electrically active contact region and lead-in region, wherein the at least one channel passes through the at least one additional metal layer to expose the second metal layer; and
(c) forming a defect in the component in at least one predetermined location around the at least one channel, wherein the defect passes through the at least one additional metal layer to expose the second metal layer, through the at least one additional metal layer and second metal layer to expose the first metal layer, or a combination thereof.

9. The method of claim 8, wherein the first metal layer comprises copper or a copper alloy.

10. The method of claim 8, wherein the second metal layer comprises nickel.

11. The method of claim 8, wherein the at least one metal layer comprises a precious metal.

12. The method of claim 8, wherein the defect is formed using a focused ion beam.

13. The method of claim 8, further comprising a plurality of defects, wherein the plurality of defects includes (a) a single line of individual defects formed partially or completely around the electrically active contact region and lead-in region, or (b) an array of individual defects formed partially or completely around the electrically active contact region and lead-in region.

14. The method of claim 8, wherein the defect includes a single continuous defect formed partially or completely around the electrically active contact region.

15. A method for inhibiting corrosion in metal components, comprising:
(a) providing a component, wherein the component includes an electrically active contact region; and
(b) forming at least one defect on the component in at least one predetermined location around the electrically active contact region, wherein the defect includes at least one sacrificial material deposited on the component.

16. The method of claim 15, wherein the electrically active contact region further includes a precious metal.

17. The method of claim 15, wherein the sacrificial material is copper, silver, zinc, or a combination thereof.

18. The method of claim 15, further comprising a plurality of defects, wherein the plurality of defects includes (a) a single line of individual defects formed partially or completely around the electrically active contact region, or (b) an array of individual defects formed partially or completely around the electrically active contact region.

19. The method of claim 15, wherein the defect includes a single continuous defect formed partially or completely around the electrically active contact region.

20. The method of claim 15, wherein the defect is formed using predetermined plating techniques, e-beam deposition, ink-jetting, or a combination thereof.

21. The method of claim 18, further comprising depositing at least one strip of sacrificial material between the electrically active contact region and the plurality of defects.

22. The method of claim 21, wherein the at least one strip of sacrificial material is formed using predetermined plating techniques, e-beam deposition, ink-jetting, or a combination thereof.
